(19) United States
(12) Patent Application Publication
(10) Pub. No.: US 2008/0173892 A1
(43) Pub. Date: Jul. 24, 2008

(54) PACKAGE STRUCTURE

(75) Inventor: Wei-An Chen, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: LIGHTHOUSE TECHNOLOGY CO., LTD, Hsin-Chu Hsien (TW)

(21) Appl. No.: 11/683,437

(22) Filed: Mar. 8, 2007

(30) Foreign Application Priority Data
Jan. 23, 2007 (TW) 96201274

(51) Int. Cl. H01L 33/00

(52) U.S. Cl. 257/99; 257/E33.059

(57) ABSTRACT

A package structure including a carrier, a molding element and a chip is provided. A part of the carrier is enclosed by the molding element. The molding element has a top portion and a bottom portion opposite to the top portion, wherein the top portion has a cavity exposing a part of the carrier and the bottom portion has a first protrusion and two second protrusions located at both sides of the first protrusion. The chip is disposed in the cavity and electrically connected to the carrier.

### CROSS-REFERENCE TO RELATED APPLICATION

This application claims the priority benefit of Taiwan application serial no. 96201274, filed Jan. 23, 2007. All disclosure of the Taiwan application is incorporated herein by reference.

### BACKGROUND OF THE INVENTION

1. Field of the Invention

The present invention generally relates to a package structure, and more particularly, to a LED (light-emitting diode) chip package structure.

2. Description of Related Art

In comparison with traditional bulbs, LEDs are much superior in, for example, for example, compact size, longer lifetime, electricity-saving and no mercury-related pollution. Therefore, along with continuously increasing luminous efficiency, LEDs have gradually substitute fluorescent lamps and incandescent lamps in some applications. For example, all the following applications requiring fast response characteristic have employed LEDs such as light source of scanner, backlight source of LCDs, dashboard lighting of vehicle, traffic light and lighting device.

FIG. 1A and FIG. 1B are respectively a top view and a front view of a conventional LED package structure. Referring to FIGS. 1A and 1B, a conventional LED package structure 100 includes a lead frame 110, a molding element 120 and an LED chip 130. The lead frame 110 includes a first lead 112 and a second lead 114, and the molding element 120 encloses parts of the first lead 112 and the second lead 114. The molding element 120 has a cavity 122. The LED chip 130 is disposed in the cavity 122 and electrically connected to the first lead 1 12 and the second lead 114.

The molding element 120 is fabricated by using an injection molding process in the prior art. Since the mold for the injection molding process is designed according to the single runner configuration, wherein the mold has an encapsulant inlet, thus after the molding element 120 is formed, there is a round protrusion 124 remaining on the bottom of the molding element 120.

With the conventional mold is designed according to the single runner configuration, if the side walls around the cavity 122 are thinner, it tends to produce excessive hydraulic resistance and generate bubbles during injection molding, which further leads to a number of voids inside the molding element 120. In other words, the quality of the molding element 120 fabricated in such a process is poor. In addition, the shape of the cavity 122 of the molding element 120 and the taper angle of the side walls of the cavity 122 in the prior art are mostly designed without considering some issues, such as the wall thickness of the side walls of the cavity 122 and the reflection of the light emitted from the LED chip, so that the light-emitting efficiency of the LED package structure 100 is poor.

### SUMMARY OF THE INVENTION

Accordingly, the present invention is directed to a package structure where the formation of voids in the molding element is reduced and the problems occurring due to formation of voids in the molding element is reduced.

As embodied and broadly described herein, the present invention provides a package structure including a carrier, a molding element and a chip. The molding element encloses a part of the carrier and the molding element has a top portion and a bottom portion opposite to the top portion, wherein the top portion has a cavity to expose a part of the carrier, while the bottom portion has a first protrusion and two second protrusions located at both sides of the first protrusion. The chip is disposed in the cavity and electrically connected to the carrier.

In the above-mentioned package structure, the thickness of the first protrusion is, for example, greater than the thickness of the second protrusion.

In the above-mentioned package structure, the second protrusions are, for example, a round protrusion.

In the above-mentioned package structure, a side of the molding element has, for example, a third protrusion, and parts of the carrier located at both sides of the third protrusion are exposed.

In the above-mentioned package structure, the two opposite sides of the bottom portion respectively have a fourth protrusion, and the first protrusion and the second protrusions are located between the two fourth protrusions.

In the above-mentioned package structure, the cross section of the cavity is, for example, gradually shrunk along a direction from the top end to the bottom end of the cavity.

In the above-mentioned package structure, the profile of the cavity is, for example, a narrow polygon.

The above-mentioned package structure further includes an encapsulant covering the chip, wherein the refractive index of the encapsulant ranges, for example, between 1.06 to 5, and the included angle between the two opposite side walls of the cavity ranges, for example, from 30 degree to 150 degree.

In the above-mentioned package structure, the carrier is, for example, a lead frame. The lead frame includes a first lead and a second lead. The chip is disposed on the first lead and electrically connected to the first lead and the second lead.

In the above-mentioned package structure, the chip is, for example, an LED chip.

In the above-mentioned package structure, the second protrusions are located on a same plane.

In the above-mentioned package structure, the second protrusions are located on two different planes.

In the present invention, the two second protrusions on the bottom portion of the molding element are adapted to an injection mold designed according to a double runner configuration. Since the mold has double runners, the phenomena of excessive hydraulic resistance during inject molding can be improved, which facilitates to reduce bubbles and thereby reduce the voids within the molding element.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are respectively a top view and a front view of a conventional LED package structure.

FIG. 2 is a schematic 3D-drawing of a package structure according to an embodiment of the present invention.

FIGS. 3A-3C are respectively a top view, a front view and a bottom view of the package structure shown by FIG. 2.

FIG. 4 is a schematic cross-sectional drawing of the package structure shown by FIG. 2.

FIG. 5 is a diagram of a package structure according to another embodiment of the present invention.

FIG. 6 is a diagram of a package structure according to another yet embodiment of the present invention.

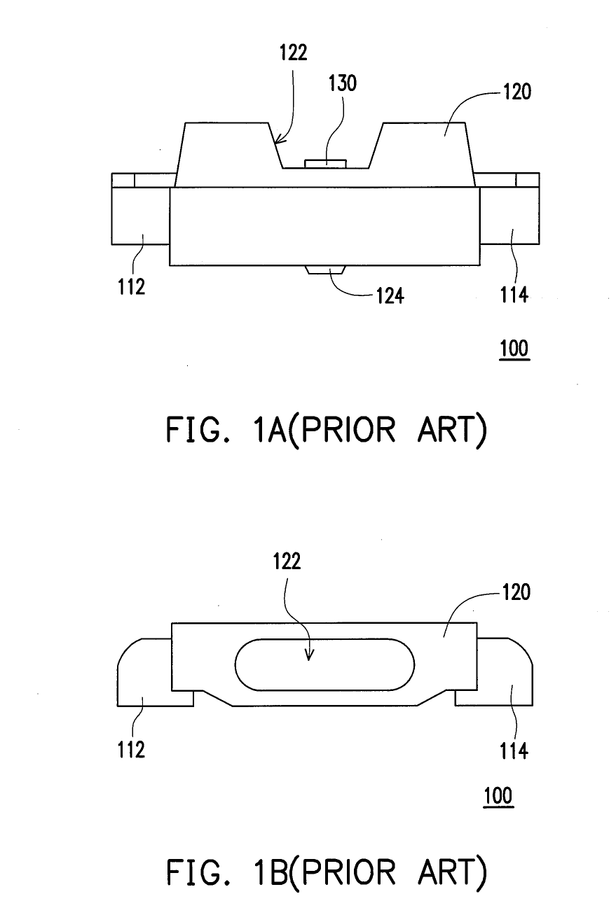

### DESCRIPTION OF THE EMBODIMENTS

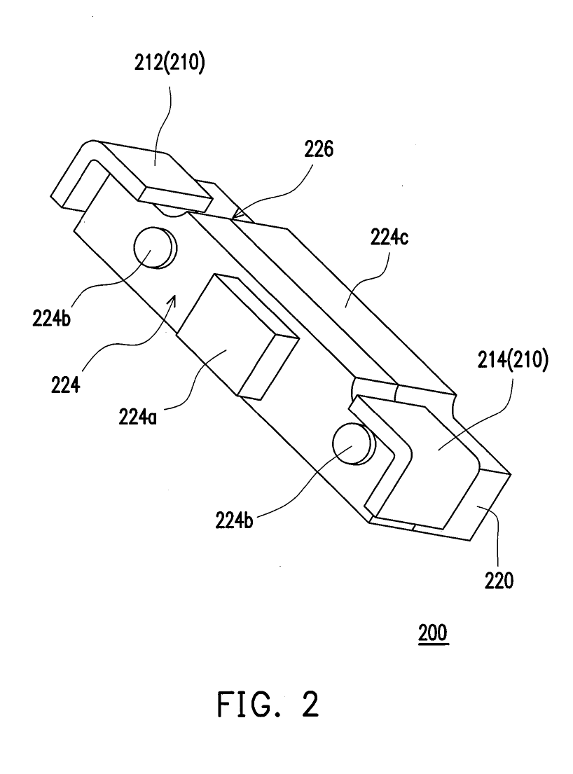

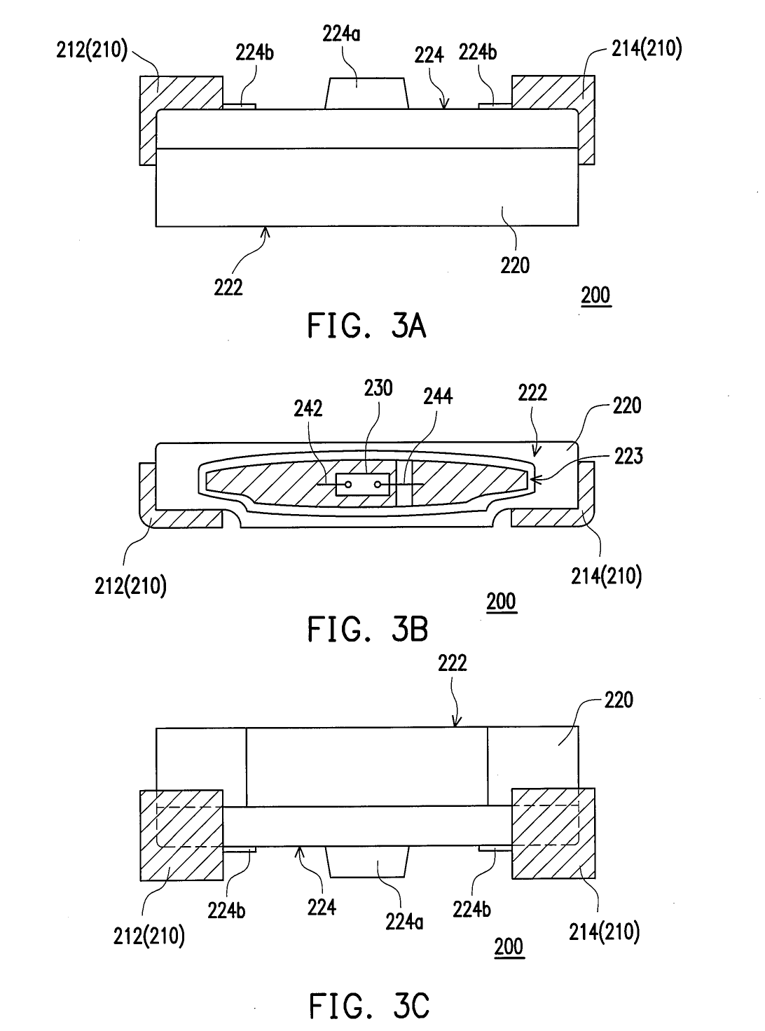

FIG. 2 is a schematic 3D-drawing of a package structure according to an embodiment of the present invention, while FIGS. 3A-3C are respectively a top view, a front view and a bottom view of the package structure shown by FIG. 2. Referring to FIGS. 2 and 3A-3C, a package structure of the present embodiment 200 includes a carrier 210, a molding element 220 and a chip 230. The molding element 220 encloses a part of the carrier 210 and the molding element 220 has a top portion 222 and a bottom portion 224 opposite to the top portion 222, wherein the top portion has a cavity 223 to expose a part of the carrier 210, while the bottom portion 224 has a first protrusion 224a and two second protrusions located at both sides of the first protrusion 224a. The chip 230 is disposed in the cavity 223 and electrically connected to the carrier 210.

In the above-mentioned package structure 200, the carrier 210 is, for example, a lead frame which includes a first lead 212 and a second lead 214. The chip 230 is, for example, disposed on the first lead 212 and electrically connected to the first lead 212 and the second lead 214. In more detail, the chip 230 is electrically connected to the first lead 212 via a soldering wire 242 and to the second lead 214 via the soldering wire 244. In addition, the chip 230 is, for example, an LED chip, and the emitted light therefrom would be emitted out from the top end of the cavity 223.

A side 226 of the molding element 220 has, for example, a third protrusion 224c, and parts of the carrier 210 located at both sides of the third protrusion 224c are exposed. In more detail, a part of the first lead 212 and a part of the second lead 214 are exposed at both sides of the third protrusion 224c.

In the present embodiment, the molding element 220 is fabricated by using an injection molding process and the injection mold has double runners, i.e. the die has two encapsulant inlets. Thus, after forming the molding element 220, two second protrusions 224b are produced on the bottom portion 224 thereof. The second protrusions 224b are, for example, a round protrusion. In addition, a first protrusion 224a is formed between the second protrusions 224b, and the thickness of the first protrusion is, for example, greater than the thickness of the second protrusions 224b.

The double runners in the injection mold can reduce the phenomena of excessive hydraulic resistance during inject molding for the side walls around the cavity 223 with a thinner wall thickness, which facilitates to reduce number of bubbles, and lower the voids inside the molding element 220 and promotes the quality of the molding element 220. Besides, since the encapsulant may be injected into the die simultaneously from two encapsulant inlets, therefore, it facilitates to reduce time to form the molding element 220, and thereby increase production efficiency.

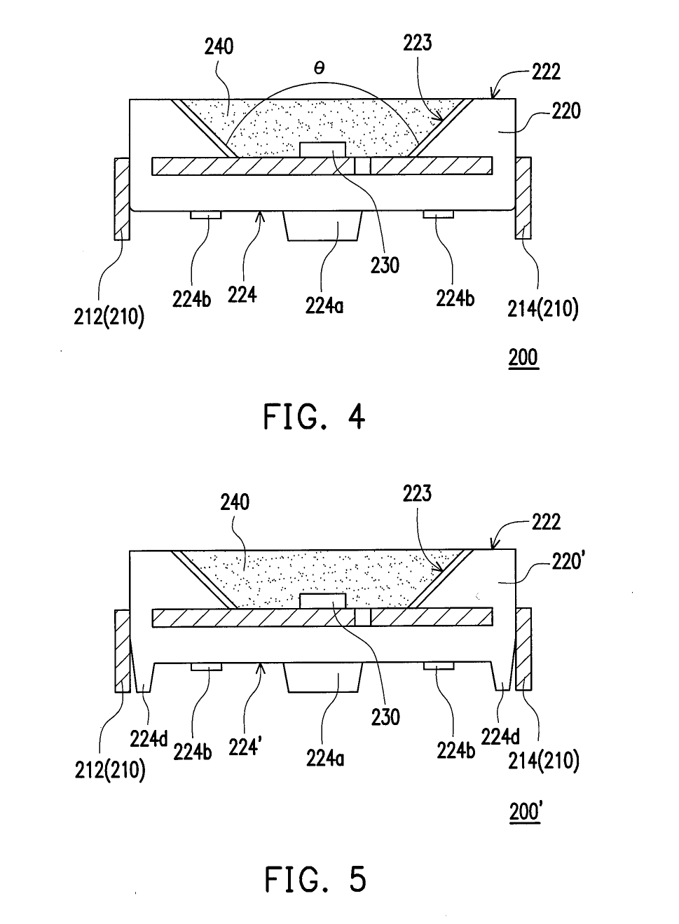

FIG. 4 is a schematic cross-sectional drawing of the package structure shown by FIG. 2. Referring to FIGS. 3B and 4, the package structure 200 in the embodiment further includes, for example, an encapsulant 240 covering the chip 230. The profile of the cavity 223 is, for example, a narrow polygon. Besides, in order to promote the light-emitting efficiency of the light produced by the chip 230 exiting from the cavity 223, the cross section of the cavity 223 is, for example, gradually shrunk along a direction from the top end to the bottom end of the cavity. Furthermore, the material of the encapsulant 240 has a refractive index between 1.05 and 5, and the included angle between the two opposite side walls of the cavity 223 is, for example, between 30° and 150°.

FIG. 5 is a diagram of a package structure according to another embodiment of the present invention. Referring to FIG. 5, the package structure 200′ of the embodiment is similar to the above-described package structure 200 except the molding element 220′, wherein at two opposite sides of the bottom portion 224′ of the molding element 220′ in the present embodiment there is respectively a fourth protrusion 224d, and the first protrusion 224a and the second protrusions 224b are located between the two fourth protrusions 224d. The package structure 200′ of the embodiment has the same advantages as the package structure 200.

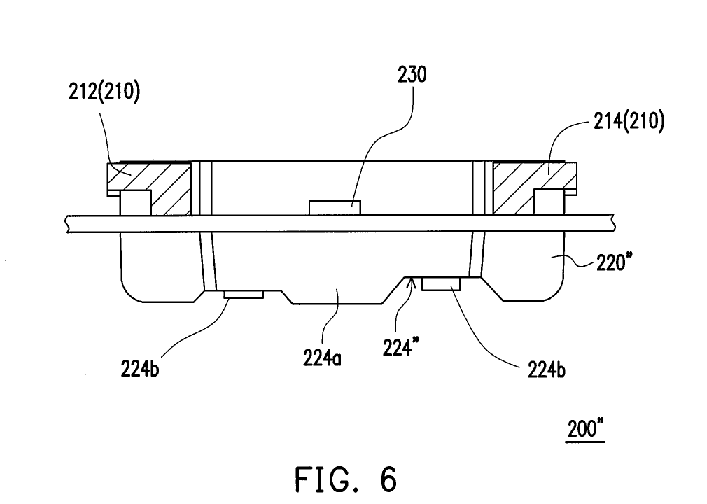

FIG. 6 is a diagram of a package structure according to another yet embodiment of the present invention. Referring to FIG. 6, compared to the above-described package structures 200 and 200′ where two second protrusions 224b are located on a same plane, the two second protrusions 224b of the molding element 220″ in the package structure 200″ of the present embodiment are located on different planes. In other words, the present invention does not limit the two second protrusions 224b to be on a same plane. Besides, compared to the molding element 220 in FIG. 2 where the width of the first protrusion 224a is different from the width of the bottom portion 224 of the molding element 220, the width of the first protrusion 224a in the present embodiment can be the same as the width of the bottom portion 224″ of the molding element 220″.

In summary, the molding element of the present invention has at least the following advantages.

1. The two second protrusions of the bottom portion of the molding element are adapted to an injection mold designed to implement a double runner configuration, which is may reduce the phenomena of excessive hydraulic resistance during inject molding of the side walls around the cavity with a thinner wall thickness, so that the number of bubble and the voids inside the molding element after forming can be reduced and thereby promote the quality of the molding element.

2. Since the encapsulant are simultaneously injected into the mold from two encapsulant inlets, the present invention can reduce the time for forming the molding element and increase the production efficiency.

3. A limited refractive index range of the encapsulant and a limited included angle range between the two opposite side walls of the cavity of the molding element are able to effectively promote the light-emitting efficiency of the light produced by the chip and exit from the cavity.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A package structure, comprising:
a carrier;
a molding element, enclosing a part of the carrier and having a top portion and a bottom portion opposite to the top portion, wherein the top portion has a cavity exposing a part of the carrier and the bottom portion has a first protrusion and two second protrusions located at both sides of the first protrusion; and
a chip, disposed in the cavity and electrically connected to the carrier.

2. The package structure according to claim 1, wherein the thickness of the first protrusion is greater than the thickness of the second protrusion.

3. The package structure according to claim 1, wherein the second protrusions comprise a rounded protrusion.

4. The package structure according to claim 1, wherein a side of the molding element has a third protrusion and parts of the carrier are exposed at both sides of the third protrusion.

5. The package structure according to claim 1, wherein the two opposite sides of the bottom portion respectively have a fourth protrusion, and the first protrusion and the second protrusions are located between the fourth protrusions.

6. The package structure according to claim 1, wherein a cross section of the cavity is gradually shrunk along a direction from the top end to the bottom end of the cavity.

7. The package structure according to claim 6, wherein a profile of the cavity comprises a narrow polygon.

8. The package structure according to claim 7, further comprising an encapsulant covering the chip, wherein the refractive index of the encapsulant is between 1.06 and 5, and the included angle between the opposite two side walls of the cavity is between 30 degree and 150 degree.

9. The package structure according to claim 1, wherein the carrier comprises a lead frame, the lead frame comprises a first lead and a second lead and the chip is disposed on the first lead and electrically connected to the first lead and the second lead.

10. The package structure according to claim 1, wherein the chip is a light-emitting diode chip.

11. The package structure according to claim 1, wherein the second protrusions are located on a same plane.

12. The package structure according to claim 1, wherein the second protrusions are located on different planes.
